(19) United States
(12) Patent Application Publication
(10) Pub. No.: US 2022/0010426 A1
(43) Pub. Date: Jan. 13, 2022

(54) COATINGS THAT CONTAIN FLUORINATED YTTRIUM OXIDE AND A METAL OXIDE, AND METHODS OF PREPARING AND USING THE COATINGS

(71) Applicant: ENTEGRIS, INC., Billerica, MA (US)

(72) Inventors: Carlo WALDFRIED, Middleton, MA (US); Stephen LONGO, Westford, MA (US)

(21) Appl. No.: 17/370,810

(22) Filed: Jul. 8, 2021

Related U.S. Application Data
(60) Provisional application No. 63/050,063, filed on Jul. 9, 2020.

(51) Int. Cl. C23C 16/40; C23C 16/56; C04B 35/515; C04B 35/553; C04B 35/488; C04B 35/622

(52) U.S. Cl. CPC C23C 16/405; C23C 16/56; C04B 35/5156; C04B 2235/3244; C04B 35/488; C04B 35/62222; C04B 2235/445; C04B 35/553

(57) ABSTRACT

Described are coatings that contain of fluorinated yttrium oxide and a metal oxide; methods of preparing these coatings; substrates, surfaces, equipment, and components of equipment that include a coating that contains a combination of fluorinated yttrium oxide and a metal oxide; and methods of preparing and using the coatings and coated substrates.

### FIELD

The present description relates to coatings that contain a combination of fluorinated yttrium oxide (e.g., yttrium fluoride, yttrium oxyfluoride, or a combination thereof) and a metal oxide such as (but not limited to) zirconium oxide, including protective coatings; methods of preparing these coatings; substrates, surfaces, equipment, and components of equipment that include a coating that contains a combination of fluorinated yttrium oxide and a metal oxide; and methods of preparing and using the substrates.

### BACKGROUND

Semiconductor and microelectronic device manufacturing methods require various processing steps that involve highly reactive process materials such as plasmas, acids, accelerated ions, etchants (e.g., halogens and halogenated materials), corrosive materials, cleaning agents, among others.

Example processes include ion implantation processes (e.g., “doping” processes), etching processes that may use a plasma or a halogen material, cleaning processes, deposition steps, among others, each of which can include the use of a reactive, corrosive, or high energy process material within a “process chamber.” Each of these types of processes is performed at an interior of a process chamber that contains a workpiece (e.g., “substrate”) and the process materials. The process chamber also includes various structures and components (sometimes referred to herein as “process chamber components” or “process tool components” for short) that define the process chamber and items internal to the process chamber or items associated with the chamber, and that are required for operation. These process chamber components may include chamber walls, flow conduits (e.g., flow lines, flow heads, piping, tubing, and the like), fasteners, trays, supports, and other structures and devices that are used to support a workpiece or to deliver, contain, or otherwise contact a reactive process material for use within the process chamber.

For use as part of a process chamber, a process tool component should be resistant to the reactive process materials that will be used within the process chamber. A process chamber component should not become degraded or damaged by contact with the process materials, especially in a manner that would produce debris or particulates that may become incorporated into the process that is being performed and potentially contaminate a workpiece being processed.

Process chamber components used in semiconductor processing equipment for manufacturing semiconductor and microelectronic devices are frequently made of a solid material (a “substrate” or a “base”) such as a metal (e.g., stainless steel, aluminum alloy which may optionally be anodized, tungsten), a mineral, or ceramic material, etc. The substrate is usually coated with a protective layer that is more resistant to reactive process materials than is the substrate material. In the past, such protective coatings have typically been placed onto a substrate surface by various useful methods, typically by a process of anodizing (e.g., to produce anodized aluminum), spray coating, or a deposition method such as physical vapor deposition (PVD), chemical vapor deposition (CVD), atomic layer deposition (ALD), or a modification or derivative of one of those.

### SUMMARY

The present description relates to deposited coatings that can be prepared to contain both fluorinated yttrium oxide (e.g., yttrium fluoride, yttrium oxyfluoride, or both) and a metal oxide, in combination. A coating can be used as a protective coating, especially as a protective coating that is chemically resistant to reactive chemicals (process materials) used in methods of processing semiconductor or microelectronic devices. As used herein, the term “fluorinated yttrium oxide” refers to yttrium oxide that has been subject to a step of fluorination. The term includes the compounds known as yttrium fluoride (YF₃) and yttrium oxyfluoride (YOF). The term “fluorinated yttrium oxide” may sometimes, in the chemical arts, be used to refer to the compound yttrium oxyfluoride having the formula YOF. But for purposes of the present description, the term “yttrium oxyfluoride” will refer to the compound YOF, and “fluorinated yttrium oxide” will refer to compounds derived by fluorinating yttrium oxide, and will include both yttrium fluoride (YF₃) and yttrium oxyfluoride (YOF).

Also according to the present description, the coatings may be prepared by methods that use atomic layer deposition techniques to place a non-fluorinated yttrium oxide precursor coating onto a surface, followed by a step of fluorinating the precursor by a fluoro-annealing step to produce fluorinated yttrium oxide. The precursor coating contains yttrium oxide and metal oxide. The fluoro-annealing step converts a substantial portion of the yttrium oxide to fluorinated yttrium oxide, meaning yttrium fluoride, yttrium oxyfluoride, or a combination of these, to form a resultant coating that contains a combination of the metal oxide (which is not fluorinated) and the fluorinated yttrium oxide, i.e., a “fluorinated yttrium oxide-metal oxide coating.”

Methods of forming fluorinated yttrium oxide-metal oxide coatings as described, by atomic layer deposition, have been identified as particularly effective for producing coatings that contain high amounts of fluorinated yttrium oxide and a metal oxide. Methods as described have been shown to be especially effective for forming a coating that contains high concentrations of fluorinated yttrium oxide and metal oxide, with zirconium oxide as a preferred metal oxide, as compared to alternative deposition methods that involve other techniques of depositing yttrium oxide (e.g., chemical vapor deposition, physical vapor deposition, or variations of these) followed by a fluoro-annealing step. Methods of the present description are also particularly effective when the non-yttrium metal oxide is zirconium oxide, which has been identified as being especially effective in allowing fluorination of yttrium oxide beneath a surface of an yttrium oxide-metal oxide coating.

A coating as described can exhibit a useful combination of properties and effects of the fluorinated yttrium oxide and the metal oxide materials in a single atomic layer deposition coating. Fluorinated yttrium oxide is effective as a protective coating material because both yttrium fluoride and yttrium oxyfluoride contain a high level of fluorine and provides a high level of chemical inertness against reactive process materials that contain fluorine. Yttrium fluoride and yttrium oxyfluoride do not necessarily show the same high level of chemical resistance to other reactive process materials. Often, reactive process materials may include a combination of two or more different reactive chemicals, such as combination of fluorine with another reactive chemical. To improve resistance relative other process materials, e.g., that may be used in combination with fluorine, a non-yttrium metal oxide may be included in the coating. One example of such a metal oxide is zirconium oxide, but other metal oxides may also provide chemical resistance that is complementary to fluorinated yttrium oxide.

### BRIEF DESCRIPTION OF THE DRAWINGS

FIG. 1 shows an example of a coated substrate as described.

FIGS. 2A, 2B, and 2C show examples of coated substrates as described, with various types of multi-layer coatings.

FIG. 3 shows an example of steps of methods of the description.

FIG. 4 is a table of data of compositions of coatings as described.

All drawings are schematic and not to scale.

### DETAILED DESCRIPTION

The following description relates to deposited coatings, e.g., “films,” that contain both fluorinated yttrium oxide and a metal oxide (different from yttrium oxide), in combination (sometimes referred to herein, for convenience, as “fluorinated yttrium oxide-metal oxide coatings” or “fluorinated yttrium oxide-metal oxide films”). “Fluorinated yttrium oxide” refers to yttrium oxide, yttrium oxyfluoride, and combinations of these.

The description also relates to fluorinated yttrium oxide-metal oxide coatings used as a protective coating on a substrate, and to substrates, process equipment, and components of process equipment that include a fluorinated yttrium oxide-metal oxide coating. In example uses, fluorinated yttrium oxide-metal oxide coatings may perform as a protective coating that is chemically resistant to reactive chemicals (process materials) used in methods of processing semiconductor or microelectronic devices.

The description also relates to methods for preparing fluorinated yttrium oxide-metal oxide coatings. The coatings may be prepared by methods that use atomic layer deposition techniques to place a non-fluorinated yttrium oxide precursor coating onto a surface, followed by a step of fluorinating the precursor by a fluoro-annealing step. The precursor coating contains yttrium oxide and metal oxide, and the fluoro-annealing step converts a substantial portion of the yttrium oxide to fluorinated yttrium oxide, to form a resultant fluorinated yttrium oxide-metal oxide coating.

A surface of a substrate that includes the fluorinated yttrium oxide-metal oxide coating may optionally be a highly three-dimensional surface, for instance a surface that has at least one structure that exhibits a high aspect ratio. The surface may be one that is used as a component of a chemical processing or manufacturing apparatus, such as for semiconductor or microelectronic device processing.

A described coating is resistant to reactive process materials, especially (but not only): process materials used for etching techniques used in semiconductor and microelectronic processing methods; and process materials used in methods and steps for cleaning a process chamber of an apparatus (“tool”) used in semiconductor and microelectronic processing methods. Specific reactive process materials used in these methods include halogens and halogen-containing materials such as fluorine, chlorine, fluorine-, or chlorine-containing materials, and mixed halogens (i.e., combinations of two or more different halogens) such as a combination of fluorine and chlorine. The reactive process material may be in a form of a liquid or a vapor (including plasma).

According to the present description, coatings that contain a combination of fluorinated yttrium oxide and a metal oxide other than yttrium oxide have been identified as useful or particularly effective (e.g., advantageously expected) as protective, chemical resistant (inert) coatings, due to the coating containing a combination of both fluorinated yttrium oxide and another metal oxide. (As used herein, unless otherwise noted, the term “metal oxide” as part of a fluorinated yttrium oxide-metal oxide coating or a precursor or derivative thereof refers to a non-yttrium metal oxide.)

These coatings can provide a useful combination of properties and effects of the fluorinated yttrium oxide and the metal oxide materials in a single atomic layer deposition coating. Fluorinated yttrium oxide is effective as a protective coating material because fluorinated yttrium oxide contains a high level of fluorine and provides a high level of chemical inertness against reactive process materials that contain fluorine. But fluorinated yttrium oxide does not necessarily show the same high level of chemical resistance to other reactive process materials, such as reactive process materials that contain chlorine. To improve resistance relative to reactive process materials that contain chlorine, a non-yttrium metal oxide such as zirconium oxide is included in the coating. Zirconium oxide has improved chemical resistance to reactive process materials that contain chlorine, and a coating that contains both fluorinated yttrium oxide and zirconium oxide is effective as a coating that exhibits useful or advantageous chemical resistance to both fluorine-containing and chlorine-containing process materials.

A coating as described can be included on any surface or substrate that may desirably include a protective (e.g., chemically inert, non-reactive) coating. A coating may be formed on a substrate to form a “coated article” (such as a coated process tool component) with the coating applied to a surface of the substrate in a solid continuous form or alternately in a patterned form. Examples of coated articles include items such as any of various components of a process chamber (“process tool components”) that is used for preparing semiconductor materials, microelectronic devices, and the like. Being resistant to process materials such as halides, the coating can be used on a surface of a process tool component of a process chamber that will contain these and other process materials, with reduced degradation and particle or debris formation caused at the surface.

Atomic layer deposition coatings as described include “precursor” coatings that contain yttrium oxide and metal oxide, as well as fluorinated coatings that contain fluorinated yttrium oxide and metal oxide. For convenience, these two types of coatings are sometimes referred to collectively as “yttrium-metal oxide” coatings. The coatings include a combination yttrium oxide and a metal oxide (as a precursor coating), or a combination of fluorinated yttrium oxide and metal oxide (after a fluoro-annealing step), with the two materials being applied in a series of steps by an atomic layer deposition technique, to produce the precursor, followed by a fluoro-annealing step to produce the fluorinated yttrium oxide.

Because the coatings are prepared by an atomic layer deposition technique that applies materials by multiple deposition steps, the coatings may be referred to as “multi-layer” coatings. Depending on the amount of deposited material that is applied during each individual deposition step, the resulting coating may exhibit layered structure that is detectable using magnification techniques. With a sufficient amount of material applied during each deposition step, each applied amount of material may be identified (using magnification) as a separate layer of material.

In other examples (still considered “multi-layer” coatings due to being prepared by a series of atomic layer deposition steps) the amount of material deposited with each individual deposition step is less than an amount that is sufficient to form a distinct (detectable) layer in a resultant coating structure. For example, a coating may be deposited by atomic layer deposition steps that deposit separate amounts of materials (as described) at thicknesses that are less than a roughness of the surface onto which the material is deposited. When deposited in succession, deposited amounts of different deposited materials fail to form distinct “layers,” but instead form a “composite” material made from the different deposited materials without forming discrete layers, e.g., do not form even a monolayer having a thickness of from 1 to 5 atoms thick. By these methods, the resulting coating does not exhibit distinct layers, but does contain at least two chemically distinct materials that include a metal oxide and yttrium oxide (as a precursor coating) or a combination of metal oxide and fluorinated yttrium oxide (after a fluoro-annealing step).

Accordingly, a used herein, the term “multi-layer” refers to atomic layer deposition coatings that have multiple, identifiable layers (e.g., using optical or electronic magnification techniques), and also refers to atomic layer deposition coatings that include materials that are deposited by a series of deposition steps at thicknesses that do not result in multiple identifiable “layers” but that produce a “composite” structure as described.

Generally, as non-limiting examples, a thickness of a single “layer,” as deposited, whether identifiable as a layer or not, of an yttrium-metal oxide coating may be in a range from less than 1 nanometer to a few or several nanometers, e.g., about 0.1, 0.5, 1, 2, 5, or 10 nanometers, up to tens or hundreds of nanometers, e.g., up to or in excess of 50, 100, 500, 600, 800, or 900 nanometers (0.9 micron). A total thickness of a multi-layer (including composite) yttrium-metal oxide coating may be in a range from 1, 5, or 10 nanometers, up to 100, 500, or 1000 nanometers (1 micron).

Certain example multi-layer coatings include coatings that are made of two or more, e.g., 2, 3, 5, or up to 10, 20, 30, 50, 100, 500, or 1000 separate and identifiable (with magnification) layers, the different layers being made of materials that include: a metal oxide (other than yttrium oxide), and an yttrium-containing layer that is yttrium oxide (as a precursor) or a fluorinated yttrium oxide-containing material (including combinations of different fluorinated yttrium oxide materials) (after a fluoro-annealing step). The different layers may each be made of one material that is a metal oxide (other than yttrium oxide), or an yttrium-containing layer that is yttrium oxide (as a precursor) or fluorinated yttrium oxide (after a fluoro-annealing step).

Optionally, a fluorinated yttrium oxide-metal oxide coating or precursor thereof may also include layers of one or more additional materials such as a second type of metal oxide. Each layer can be continuous over an area of a coating, can exhibit a discernible (measurable, identifiable) thickness, and may be made entirely or substantially of a single material (metal oxide, yttrium oxide, yttrium oxyfluoride, yttrium fluoride, etc.) having a relatively high level of purity, e.g., at least 90, 95, 98, or 99 percent by weight of a single metal oxide or yttrium-containing material as described herein. (Except, note that a layer that contains yttrium fluoride may contain yttrium fluoride in combination with an amount of non-converted yttrium oxide or fluorinated yttrium oxide).

Thicknesses of individual layers of a coating may be the same, approximately the same, or may be different. Example coatings may include individual deposited layers that exhibit the same thickness, such as two repeating layers A (e.g., fluorinated yttrium oxide or yttrium oxide) and B (a non-yttrium oxide metal oxide such as zirconium oxide), with no other layers, with each of the two different materials formed into layers of the same thickness, such as: each layer having a thickness of 1 nanometer (A=1 nanometer, B=1 nanometer)×N repetitions, (N may be from 1 to 50 or 5 to 100 or 10 to 500) for a total of from 2 to 100 total layers or 10 to 200 layers or 20 to 1000 layers.

A different example coating may include deposited layers of two different materials, with the layers of different materials having different thicknesses but with layers of the same material having the same thickness. An example coating may include two repeating layers: A (e.g., fluorinated yttrium oxide or yttrium oxide) and B (a non-yttrium oxide metal oxide such as zirconium oxide). Each of the A layers may all have the same thickness, which may be in a range from 1 nanometer to 50 nanometers. Each of the B layers may all have the same thickness, but that thickness may be different from the thickness of the A layers. The thickness of the B layers may be in a range from 0.1, 0.5, or 1, up to 50 nanometers. The coating may have a total of N layers of each material, e.g., (A=5 nanometer, B=from 10 to 50 nanometer, e.g., 40 nanometers)×N repetitions; N may be from 1 or 2 or 5, up to or greater than 10, 20, 30, 100, 200, etc., e.g. to produce a total thickness of up to 1000 nanometers.

As yet another example, a multi-layer coating may contain a first (single) layer of layer A (e.g., fluorinated yttrium oxide or yttrium oxide) of a first thickness, and multiple (N) repeating layers of A and B (a non-yttrium oxide metal oxide such as zirconium oxide), with no other layers. The first layer (A1) can be of any thickness as described. The multiple repeating layers (A2) and B can also have any useful thicknesses, such as A1 having a thickness that is different from A2, e.g., A1 is thicker than A2.

As one more example, a multi-layer coating may contain multiple, optionally repeating, pairs of A and B layers; (A is a fluorinated yttrium oxide or yttrium oxide B is a non-yttrium oxide metal oxide such as zirconium oxide). A coating may contain a first pair of A and B layers, A1/B1, which may repeat, with A1 and B1 each having a first thickness. The coating may contain a second pair of A and B layers, A2/B2, which may repeat, with A2 and B2 each having a second thickness. The coating may contain a third pair of A and B layers, A3/B3, which may repeat, with A3 and B3 each having a third thickness.

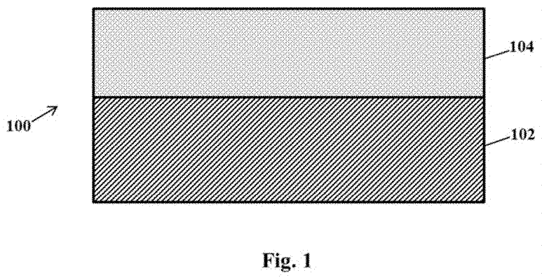

Referring to FIG. 1, illustrated is a an example of an inventive process chamber component 100 (or another type of coated device, coated article, coated substrate, etc.) made of solid body (e.g., substrate) 102 and coating 104, which includes at least one each of a layer A (e.g., fluorinated yttrium oxide or yttrium oxide) and a layer B (a non-yttrium oxide metal oxide such as zirconium oxide). In some embodiments, coating 104 may include multiple alternating layers of A and B, as described herein. Coating 104 may consist of or consist essentially of alternating layers of layer A and layer B. Alternately, coating 104 may contain multiple layers that include one or more layer A and one or more layer B, with optional added layers or materials as part of coating 104. Process chamber component 100 may consist of or consist essentially of coating 104 and solid body 102, or alternately may contain one or more optional materials, layers, or coatings as part of process chamber component 100.

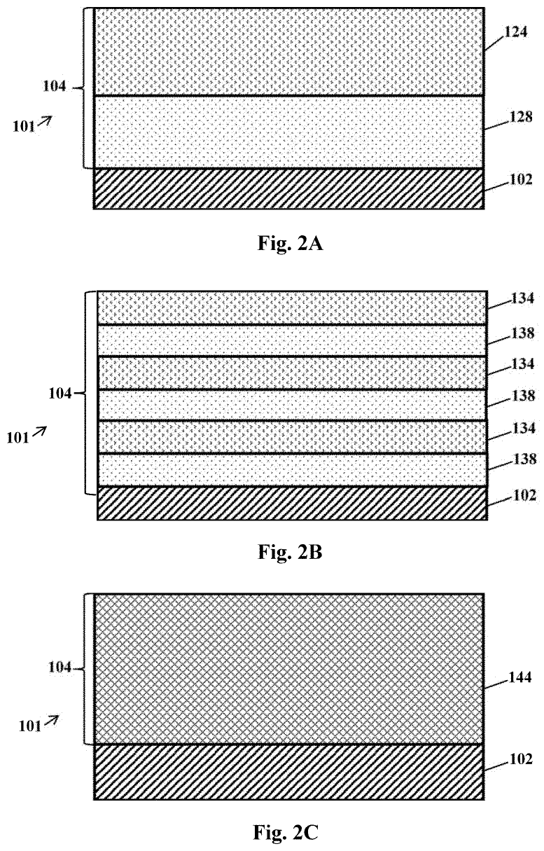

FIG. 2A shows a specific example of an inventive process chamber component 101 that includes solid body 102 and multi-layer coating 104, which is made of two layers of materials (i.e., a “bi-layer” coating): one layer (124) of material A (e.g., fluorinated yttrium oxide or yttrium oxide) and one layer 128 of material B (a non-yttrium oxide metal oxide such as zirconium oxide). The illustrated multi-layer coating 104 is shown as consisting of only the two types of illustrated layers. Each layer, 124, 128, can preferably have a high purity, such as a purity of at least 90, 95, 98, or 99 percent by weight material A or material B. Each layer may be continuous over the surface of solid body 102, and may have a thickness in a range of from less than 1 nanometer, e.g., about 1, 2, 5, or 10 nanometers, up to or greater than 50, 100, 200, 500, 800, or 900 nanometers (0.9 micron). In related examples, another different material such as a different metal oxide may be included as part of multi-layer coating 104. That is, while not illustrated, additional layers of a different type of material (e.g., a metal oxide, or otherwise) are not excluded and may be present but may not be necessary or preferred as part of multi-layer coating 104 or process chamber component 101.

FIG. 2B shows an example of a different inventive process chamber component 101 made of solid body 102 and multi-layer coating 104, made of materials as described, formed into many (e.g., tens, hundreds, or thousands) individual layers. Each layer 134 can be made of yttrium oxide (as-deposited) or of fluorinated yttrium oxide (after a fluoro-annealing step). Each layer 138 can be made of a metal oxide, such as zirconium oxide. Each layer can preferably have a high purity, such as a purity of at least 90, 95, 98, or 99 percent by weight material A or material B. Each layer may be continuous over the surface of solid body 102 and may have a thickness in a range from of less than 1 nanometer, e.g., from about 0.1, 0.5, 1, 2, 5, or 10 nanometers, up to 10, 15, or 20 nanometers. Other layers of different materials are not necessarily excluded from coating 104 or process chamber 101, and may be present although are not illustrated.

Multi-layer coating 104 of FIG. 2B, containing tens, hundreds, or thousands of layers, may be referred to as a “laminate” coating. A laminate coating can be applied to a surface of solid body 102 by a series of atomic layer deposition steps by exposing the surface to a sequence of gaseous precursor materials that will sequentially form each of the individual layers made of a single deposited material. Each continuous amount of deposited material is considered to be a “layer.” By an example, a series of atomic layer deposition steps can be performed, each step using a single precursor material to form a single deposited layer. The resulting laminate coating includes discrete “layers” due to the multi-step process by which identifiable layers of deposited material are deposited.

The laminate is considered to be made of different layers, one produced by each atomic layer deposition step, even though the discrete “layers” of different deposited materials may be challenging to identify by use of known techniques. In some laminate coatings, discrete layers may be detectable using a tunneling electron microscope. Each layer may be considered to constitute a “monolayer,” as that term is used in the chemical deposition arts, and which refers to an amount of a deposited material that has been deposited onto a surface of a substrate or to a previous ALD layer such that the deposited material saturates reaction sites on the substrate or previous ALD layer. A monolayer has a thickness of only a small number of atoms, i.e., a thickness of a single layer of atoms or molecules that cover the surface by associating with the limited number of reaction sites at the surface to produce a monolayer having a thickness of not more than about 2, 3, or 5, atoms.

FIG. 2C shows an example of yet a different inventive process chamber component 101 made of solid body 102 and coating 104 in the form of a composite (144) made of metal oxide and yttrium oxide (as deposited) or fluorinated yttrium oxide (after a fluoro-annealing step). The composite can be formed also by atomic layer deposition, as with a “laminate” coating, by a series of atomic layer deposition steps, but with the amount of each material that is deposited during each step of the series being an amount that will not produce a uniformly-deposited and detectable layer of the deposited barrier material. Composite 144 can preferably have a high purity, such as by containing at least 90, 95, 98, or 99 percent by weight of metal oxide and yttrium oxide (as a precursor) or of fluorinated yttrium oxide (after a fluoro-annealing step). A thickness of the composite 144 can be any useful thickness, such as a thickness in a range of from 10 to 1000 nanometers.

Examples of presently-preferred coatings are made of two (optionally only two) different materials, i.e., metal oxide (preferably zirconium oxide) and yttrium oxide (as deposited) or of fluorinated yttrium oxide (after a fluoro-annealing step). The coating may have only two layers (i.e., a bi-layer coating), may have multiple but only a few to several layers (e.g., from 3 to 10), or may be a laminate or a composite of the two deposited materials as described. For an yttrium-metal oxide coating that contains only two total layers, one layer made of metal oxide and one layer of yttrium oxide (as deposited, as a precursor) or fluorinated yttrium oxide (after a fluoro-annealing step), each layer (for example) may be about 50 nanometers, e.g., from 40 to 60 nanometers. For an yttrium-metal oxide coating that contains from 3 to 10 layers, each layer (for example) may be from 1, 5, or 10 to 20 to 40 nanometers, e.g., from 10 to 30 nanometers. These or a laminate or composite coating may have a total thickness of from 50 to 150 nanometers, e.g., from 80 to 120 nanometers.

Coatings as described may be formed by initially depositing a coating that contains yttrium oxide and metal oxide as a precursor coating, followed by a step of converting at least a portion of the yttrium oxide of the deposited coating to fluorinated yttrium oxide, e.g., yttrium fluoride, yttrium oxyfluoride, or a combination thereof. The deposited yttrium oxide, as well as the coating that contains the yttrium oxide and metal oxide, may sometimes be referred to herein as a “precursor” material or coating. Yttrium oxide (Y₂O₃, a.k.a., “yttria”) is prepared from and contains yttrium and oxygen in relative amounts (atomic) of approximately 2:3 (yttrium:oxygen). The precursor coating may contain two layers (one each of metal oxide and yttrium oxide), a few to several layers of both yttrium oxide and metal oxide, or may be a laminate or a composite made of alternately-deposited yttrium oxide and metal oxide. Methods of forming yttrium oxide by atomic layer deposition are known. See, e.g., United States Patent Publication 2018/0202047.

After depositing the yttrium oxide-metal oxide coating, the deposited coating is processed by a fluorine annealing step (“fluoro-annealing” step) that converts at least a portion of the total amount of yttrium oxide of the deposited coating to fluorinated yttrium oxide, which may be yttrium fluoride, yttrium oxyfluoride, or both.

Yttrium fluoride is an inorganic material that is made of yttrium and fluorine, with the chemical makeup of YF₃, or approximately so. Yttrium oxyfluoride is an inorganic material that is made of yttrium, fluorine, and oxygen, having the chemical makeup YOF.

The fluoro-annealing step is performed at a temperature and for a time that is effective to produce yttrium fluoride, yttrium oxyfluoride, or both. In certain example embodiments, the method produces a significant or a high amount of yttrium oxyfluoride without converting the yttrium oxide completely to yttrium fluoride. For example, at least 50, 70, 80, or 90 percent (atomic) of yttrium oxide may be converted to yttrium oxyfluoride (YOF), but not fully fluorinated to yttrium fluoride (YF₃).

In other examples, the method does not merely fluorinate the yttrium oxide to form yttrium oxyfluoride (YOF) but produces a high amount of the completely fluorinated yttrium fluoride. The temperature and amount of time of the fluoro-annealing step are sufficient according to these example methods to convert at least a substantial portion of the yttrium oxide of the deposited yttrium oxide-metal oxide coating to yttrium fluoride (YF₃), especially at a surface portion of the deposited yttrium oxide-metal oxide coating. According to useful or preferred methods, yttrium oxide that is present at least at an outer portion of the yttrium oxide-metal oxide coating, e.g., “surface portion” of the coating, including a portion of the thickness of the coating between the surface and a depth of at least 1, 5, or 10 nanometers, is converted to YF₃ with a low amount of oxygen or with substantially no oxygen, e.g., with less than 20 or 10 atomic percent oxygen, less than 5, or 3 atomic percent oxygen.

Preferred coatings can contain yttrium portions (e.g., layers) that contain mostly yttrium and fluorine atoms, i.e., in the form of yttrium fluoride or YF₃. Yttrium fluoride of a coating may also contain an amount of oxygen and various elemental combinations of yttrium, fluorine, and oxygen, such as yttrium oxyfluoride (YOF). However, certain preferred example coatings as described may contain yttrium mostly in the form of yttrium fluoride (YF₃), and an amount (concentration) of oxygen that is below an amount of oxygen that would be present in a composition that would be referred to as yttrium oxyfluoride (YOF), e.g., a coating may contain at least 80 percent (e.g., at least 85, 90, or 95 percent) (atomic) yttrium fluoride based on a total amount of yttrium fluoride, yttrium oxide, and yttrium oxyfluoride.

Because a coating as described is prepared by converting yttrium oxide of a precursor coating to fluorinated yttrium oxide, and because the method of converting the yttrium oxide to yttrium fluoride requires passage (e.g., diffusion) of fluorine from a surface of the coating to locations beneath the surface, a coating may potentially include concentrations of fluorine and oxygen that will be non-uniform in a thickness (depth) direction, i.e., a coating, or fluorinated yttrium oxide portions (e.g., layers) thereof, may contain concentrations of fluorine and oxygen that will vary in a measurable amount along a thickness (depth) of the deposited coating.

In specific examples of coatings, a fluorinated yttrium oxide-metal oxide coating contains a portion (referred to as an yttrium fluoride portion) that has been substantially converted (fluorinated) from yttrium oxide to yttrium fluoride. The yttrium fluoride portion may be one or multiple layers of yttrium fluoride, or may be yttrium fluoride material that is part of a laminate or a composite structure. The yttrium fluoride portion can preferably contain substantially only yttrium, fluorine, oxygen, an optional but relatively low amount of carbon (“C”) (e.g., up to 4 or 5 atomic percent carbon), and not more than a minor or unsubstantial amount of other materials. An yttrium fluoride portion of a coating as described may consist of Y, F, O, and C (e.g., up to 4 or 5 atomic percent carbon), or may consist essentially of Y, F, O, and C, e.g., may contain Y, F, O, and C (e.g., not more than 5 or 4 percent (atomic) carbon) and not more than 1, 0.5, 0.1, 0.05, or 0.01 atomic percent of any material different from Y, F, O, and C. A preferred yttrium fluoride portion can also contain not more than 20 percent (e.g., not more than 10 or 5 percent) oxygen (atomic percent).

By other criteria, example coatings may contain at least 70, 80, or 90 percent yttrium fluoride, based on a total (atomic) amount of yttrium fluoride, yttrium oxide, and yttrium oxyfluoride, to a depth of at least 5, 10, 30, 50, or 60 nanometers below a surface of the coating. Other preferred coatings may contain at least 80 percent yttrium fluoride, based on a total (atomic) amount of yttrium oxide, yttrium fluoride, and fluorinated yttrium oxide, to a depth of at least 100, 200, or 300 nanometers beneath the surface of the coating.

Different portions of a coating, based on varying composition at different thickness locations of the coating, can be identified and described by x-ray photoelectron spectroscopy or “XPS” techniques. These quantitative spectroscopic techniques allow for compositional analysis of a deposited coating or a layer of a coating, at a surface of the material and below the surface, over a thickness (depth) of the coating. The XPS profiling analysis can identify the elemental composition of the deposited material at different locations along the thickness of the material.

A coating of the invention can also be analyzed by x-ray diffraction to show that a layer or portion of the coating contains a substantial or high concentration of fluorinated yttrium oxide, e.g., YF₃, as opposed to other possible stoichiometric combinations of Y, F, and O. X-ray diffraction methods (XRD) are known analytical techniques for assessing atomic and molecular structures of materials, including materials of deposited films. X-ray diffraction, for example, is useful to assess structure and stoichiometry features of a deposited film of the type described herein, e.g., prepared by atomic layer deposition.

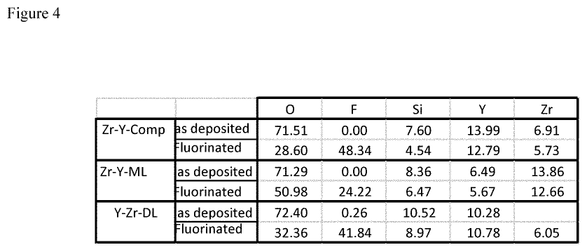

Referring to FIG. 4, this is a table that shows example data relating to the chemical makeup of example precursor coatings (“as deposited”) and the same coating after a fluoro-annealing step (“F” for fluorinated). The data is produced by energy-dispersive x-ray spectroscopy, also referred to as EDAX.

The data refers to the chemical makeup of three examples coatings, as determined by 5 keV EDAX. The Yttria-Zirconia multilayer coatings are: (a) Zr—Y-Comp=Composite of Yttria and zirconia, (b) Zr—Y-ML=Multi-layer consistent of 20 alternating layers of zirconia and Yttria, (c) Y—Zr-DL=dual layer with zirconia at the bottom and Yttria on the top, all deposited on Si substrates.

The table compares the measured atomic % values for the probed elements of Si, Zr, Y, O and F for the as-deposited coating stack (before fluorination), and again after the fluoro-anneal process. It should be noted that the EDAX atomic % values are not calibrated and absolute, but rather serve as a relative comparison between as-deposited and post-fluoro anneal conditions. The table indicates that the as-deposited yttria (Y2O3) is converted to YF3 at a high degree as a result of the fluoro-anneal process. Taking into account rationing of at % to form Y2O3, YF3 and ZrO2, the results of the table indicate that the majority of the Y2O3 is converted to YF3, while the ZrO2 does not change to a fluoride. Independent studies with zirconia have shown that zirconia does not convert to a zirconium-fluoride or zirconium-oxyfluoride.

Note that the 5 keV EDAX measurement has a probing depth between 150 nm and 200 nm, but with non-linear (higher) signal contribution from the volume that is closer to the surface. For each condition the coating film thickness is small enough for the EDAX measurement to pick up a small percentage of signal from the substrate (Si). The oxygen at % is disproportionally higher due to the typical surface oxide formation.

Methods have previously been described for converting yttrium oxide to yttrium oxyfluoride (YOF) by a fluoro-annealing step performed at a temperature below 300 degrees Celsius. See United States Patent Publication 2018/0202047. The presently-described methods now include specific features of fluoro-annealing steps performed at temperatures that exceed 300 degrees Celsius, in a manner that successfully converts yttrium oxide, at least at a surface portion of a deposited coating as described, to contain a highly concentrated amount of yttrium fluoride (YF₃) with a low amount of oxygen, substantially no oxygen, or with a low amount of yttrium oxyfluoride (YOF) or substantially no yttrium oxyfluoride (YOF).

Methods of forming fluorinated yttrium oxide-metal oxide coatings as described, by atomic layer deposition, have been identified as particularly effective for producing coatings that contain high amounts of yttrium fluoride and a metal oxide. Methods as described have been shown to be especially effective for forming a coating that contains high concentrations of yttrium fluoride and metal oxide, with zirconium oxide as a preferred metal oxide, as compared to alternative deposition methods that involve other techniques of depositing yttrium oxide (e.g., chemical vapor deposition, physical vapor deposition, or variations of these) followed by a fluoro-annealing step. Methods of the present description are also particularly effective when the non-yttrium metal oxide is zirconium oxide, which has been identified as being especially effective in allowing fluorination of yttrium oxide beneath a surface of an yttrium oxide-metal oxide coating.

Regarding deposition techniques, atomic layer deposition has improved effectiveness for forming yttrium fluoride by a fluoro-annealing step, relative to other deposition techniques. Yttrium fluoride coatings as described (i.e., coatings that contain a high degree of yttrium oxide that has been converted to yttrium fluoride) may be prepared by converting a deposited yttrium oxide thin film to yttrium fluoride by use of a relatively high temperature fluoro-annealing step, e.g., a fluoro-annealing step that is performed at a temperature of at least 300 degrees Celsius. Comparable fluoro-annealing techniques, at a relatively high temperature, attempting to convert yttrium oxide to yttrium fluoride, may be less effective when performed on yttrium oxide that is deposited by a different deposition technique, such as physical vapor deposition (“PVD”) or chemical vapor deposition (“CVD”).

These particular steps have also been determined to be more effective for forming yttrium fluoride as a metal fluoride material, compared to methods of forming other types of metal fluorides, from other metals, by comparable deposition and fluoro-annealing steps. A high temperature fluoro-annealing step as described was less effective for converting other metal oxides to metal fluorides, even for a metal oxide that had been deposited by an atomic layer deposition technique. Specifically, a fluoro-annealing step, at a relatively high temperature, was found to be less effective for converting metal oxide materials such as zirconium oxide, titanium oxide, or aluminum oxide, to a fluorinated oxide material (zirconium fluoride, titanium fluoride, or aluminum fluoride), even if the metal oxide was deposited by an atomic layer deposition technique.

Useful and preferred fluoro-annealing techniques include steps of exposing a surface of an yttrium oxide-metal oxide coating that was deposited at a surface by atomic layer deposition, to molecular fluorine source vapor at a temperature that causes fluorine of the molecular fluorine source vapor to react with yttrium oxide of the deposited yttrium oxide-metal oxide coating, to convert yttrium oxide of the coating into fluorinated yttrium oxide, preferably with a high conversion to yttrium fluoride, at and below a surface of the deposited yttrium oxide-metal oxide coating.

Preferably, to allow the molecular fluorine source to penetrate beneath the surface of the yttrium-oxide-metal oxide coating, the metal oxide of the coating should not be reactive with the molecular fluorine source vapor. For example, a preferred metal oxide will not be degraded by (e.g., “etched” by) the molecular fluorine source vapor during a fluoro-annealing step. Also preferably, the molecular fluorine source vapor will not cause fluorination of the metal oxide during the fluoro-annealing step. While the present description and invention are not limited to the use of any particular metal oxide as the non-yttrium oxide metal oxide of a fluorinated yttrium oxide-metal oxide coating, zirconium oxide is a metal oxide that has been identified as exhibiting effective or preferred properties of being resistant to degradation by molecular fluorine source vapor, and also being resistant to fluorination by molecular fluorine source vapor, during a fluoro-annealing step.

As used herein, a “molecular fluorine source vapor” is a non-plasma (i.e., molecular) fluorine-containing chemical molecule that is in vapor (gaseous) form, that is not considered a plasma. A “plasma” is a non-solid, vapor phase composition that contains a high density of ionic fragments derived from one or more plasma precursor compounds that have been deliberately exposed to energy (e.g., from a radio frequency power source) for the purpose of breaking down the plasma precursor compound into the ions, to use the ions for processing a workpiece. In contrast to a plasma, a useful or preferred molecular fluorine source vapor may contain less than 1×10E-5 atomic percent ionized materials, such as less than 1×10E-6 atomic percent ionic species.

A molecular fluorine source vapor may be provided to a process chamber for use in a fluoro-annealing step, for forming a fluorinated yttrium oxide-metal oxide coating as described, by any method or from any useful and effective source or location. In useful or preferred methods, molecular fluorine source vapor may be produced in situ, meaning during a fluoro-annealing step, and within the process chamber used for the fluoro-annealing step. The molecular fluorine source vapor may be generated in situ from a non-gaseous fluorine source by heating the non-gaseous fluorine source to cause molecules of the non-gaseous fluorine source to become gaseous, i.e., a molecular vapor. The non-gaseous fluorine source may be a liquid or a solid fluorine-containing substance, and the heating step produces the gaseous form of the molecules without causing significant degradation or ionization of the molecules of the liquid or solid fluorine source. A useful or preferred gaseous form of the molecules may be at least 99.9999 atomic percent molecular, i.e., non-chemically-changed molecules of the liquid or solid fluorine-containing substance. The gaseous form of the molecules may contain less than 1×10E-5 atomic percent ionized or degraded materials, such as less than 1×10E-6 atomic percent ionic species.

The heating step that produces a molecular fluorine source vapor is distinct from a step of generating plasma, which is used in various semiconductor processing steps. In general, plasma-generating steps involve applying one or more forms of energy to a plasma source, which is generally a gaseous chemical substance, to ionize the plasma source and chemically degrade molecules of the plasma source to produce ionic fragments of the molecules. The energy may be heat energy (elevated temperature), electromagnetic radiation such as RF (radio frequency energy) (produced by a radio frequency power source), or combinations of these.

As a specific comparison, a heating step of the present description used to produce a molecular fluorine source vapor is different from a step of generating fluorine-containing plasma for use in a semiconductor processing tool for a step of plasma etching, plasma cleaning, or “seasoning” a process chamber of a semiconductor processing tool. An example of a plasma-generating step that is different from the presently-described heating step is described in U.S. Pat. No. 5,756,222, which describes a fluorine-containing plasma generated in a reaction chamber designed for a plasma etch or plasma cleaning process. The plasma is prepared by exposing a fluorine precursor to RF power.

A fluoro-annealing step can be performed in a process chamber, at elevated temperature, by: locating a substrate at an interior of the process chamber in a removable, temporary, non-operational manner, the substrate having a surface that includes an yttrium oxide-metal oxide coating deposited thereon by atomic layer deposition; dispensing molecular fluorine source vapor into the process chamber or generating molecular fluorine source vapor within the process chamber by heating non-gaseous fluorine source to cause molecules of the non-gaseous fluorine source to become gaseous, i.e., a vapor, within the process chamber; and elevating the temperature of the process chamber, the substrate, the deposited yttrium oxide-metal oxide deposited coating, the molecular fluorine source vapor, or a combination thereof to cause a reaction between fluorine of the molecular fluorine source vapor and yttrium oxide of the deposited yttrium oxide-metal oxide coating to convert at least a portion of the yttrium oxide to fluorinated yttrium oxide, preferably to yttrium fluoride.

During the fluoro-annealing step, the process chamber may contain processing materials that include the molecular fluorine source vapor, optionally a non-vapor fluorine source, and one or more substrates that have a deposited yttrium oxide-metal oxide thin film deposited at a surface by an atomic layer deposition technique. The interior space and atmosphere of the chamber need not be evacuated or at a reduced pressure, and may contain an amount of atmospheric air. There is no need to eliminate air or oxygen or to introduce an inert gas (purge gas, e.g., N₂) into the process chamber for the fluoro-annealing step. The process chamber need not contain and may exclude any other additional gaseous or liquid processing materials besides air and the molecular fluorine source vapor, e.g., may exclude other gaseous materials such as an inert gas or a gaseous co-reactant, which may sometimes be used in a gaseous atmosphere of other semiconductor processing steps.

The process chamber is not part of a semiconductor processing tool and need not contain and preferably does not contain any other workpiece such as a semiconductor device, microelectronic device, or a precursor thereof, that is being otherwise processed. The process chamber also does not require and does not involve the use of a means for generating plasma, such as a radio frequency power source or means for applying an electrical potential (voltage) to a component or workpiece.

A useful process chamber can preferably include: temperature control to control temperature within the chamber; means to control the composition and purity of the environment interior to the chamber, such as pressure controls, filters, etc.; components to temporarily contain and support one or multiple substrates, each having a deposited yttrium oxide-metal oxide coating at a surface, within the chamber for a period useful to convert yttrium oxide of the deposited yttrium oxide-metal oxide coating into fluorinated yttrium oxide, preferably yttrium fluoride; and components to control the composition of an atmosphere within the process chamber, including to supply and control the amount and concentration the molecular fluorine source within the process chamber.

According to certain useful or preferred example fluoro-annealing methods, a molecular fluorine source vapor can be a gaseous fluorinated or perfluorinated organic compound such as a fluorinated or perfluorinated alkane or alkene, any of which may be straight or branched. Examples include CF₄, C₂F₄, C₃F₆, C₄F₈, CHF₃, C₂H₂F₂, C₂F₆, HF, CH₃F, among others, each in a molecular form, meaning substantially non-ionic and not processed (by adding energy other than heat) to degrade or form plasma.

According to other useful or preferred example methods, a molecular fluorine source vapor can be a gaseous fluorinated polymer that has not been processed with energy to form plasma. A gaseous fluorinated polymer can be derived from a non-gaseous (e.g., liquid or solid) fluorinated polymer by heating the non-gaseous fluorinated polymer, for example in a process chamber and in the presence of a deposited yttrium oxide-metal oxide coating, which is desired to be converted to fluorinated yttrium oxide by the fluoro-annealing step.

The fluorinated polymer may be any fluorinated polymer that will be effective according to a method as described for forming yttrium fluoride from a deposited yttrium oxide-metal oxide coating present on a surface of a substrate. Examples of useful fluorinated polymers include homopolymers and copolymers that include polymerized fluoroolefin monomers and optional non-fluorinated co-monomers. A polymer may be fluorinated (i.e., partially fluorinated), perfluorinated, or may include non-fluorine halogen atoms such as chlorine. A molecular fluorine source may be liquid or solid at room temperature, but will become a vapor at a temperature of a process chamber used according to a method as described.

Non-limiting examples of specific fluoropolymers include: polymerized perfluoroalkylethylene having a C₁-C₁₀ perfluoroalkyl group; polytetrafluoroethylene (PTFE); tetrafluoroethylene/perfluoro(alkyl vinyl ether) copolymer (PFA); tetrafluoroethylene/hexafluoropropylene copolymer (FEP); tetrafluoroethylene/perfluoro(alkyl vinyl ether)/hexafluoropropylene copolymer (EPA); polyhexafluoropropylene; ethylene/tetrafluoroethylene copolymer (ETFE); poly trifluoroethylene; polyvinylidene fluoride (PVDF); polyvinyl fluoride (PVF); polychlorotrifluoroethylene (PCTFE); ethylene/chlorotrifluoroethylene copolymer (ECTFE); or a combination thereof.

A fluoro-annealing step as described can be performed at any temperature that is effective to cause fluorine from the fluorine source vapor to react with yttrium oxide of a deposited yttrium oxide-metal oxide coating to convert at least a portion of the fluorine of the deposited yttrium oxide-metal oxide coating to fluorinated yttrium oxide, preferably yttrium fluoride (e.g., at a concentration and depth as described herein). A relatively high elevated temperature is generally useful or preferred, to cause the fluorine source vapor to react with the yttrium oxide to convert the yttrium oxide to a high concentration of yttrium fluoride (YF₃) instead of yttrium oxyfluoride (YOF). However, other conditions may be useful to produce coating that has a relatively lower concentration of yttrium fluoride and a relatively higher concentration of yttrium oxyfluoride (YOF), as desired.

Example temperatures of a fluoro-annealing step may be at least 300 or 350 degrees Celsius, or higher, e.g., in a range from 300 to 500 degrees Celsius, such as from 350 or 400 to 425 or 450 degrees Celsius, to produce a high concentration of YF₃ at least at a surface portion of the deposited yttrium oxide-metal oxide coating.

The process chamber can be operated at any useful pressure, with example pressures being approximately atmospheric (760 Torr), e.g., from 100 to 1500 Torr, such as from 250 or 500 to 1000 or 1250 Torr. The atmosphere within the process chamber for converting the yttrium oxide to fluorinated yttrium oxide, e.g., yttrium fluoride, may include a portion that is air, in combination with the molecular fluorine source vapor.

An amount of time used to form fluorinated yttrium oxide by a fluoro-annealing step can be based on factors such as temperature of the fluoro-annealing step, the type and amount (concentration) of molecular fluorine source vapor in the process chamber, the thickness and composition of the deposited yttrium oxide-metal oxide coating, and the desired amount (e.g., depth) of fluorination of the yttrium oxide-metal oxide coating effected by the fluoro-annealing step. Example amounts of time that are useful or preferred for a fluoro-annealing step may be in a range of from 1 to 48 hours, e.g., from 2 to 24 hours, or from 3 to 12 hours. A useful period of time for performing a fluoro-annealing step can be a period of time that converts a desired amount (e.g., in terms of depth and amount (concentration)) of the yttrium oxide of the yttrium oxide-metal oxide coating, to yttrium oxyfluoride or yttrium fluoride. The depth of the fluorination will increase over time during a fluoro-annealing step, with continued exposure of the deposited yttrium oxide-metal oxide coating to the molecular fluorine source vapor.

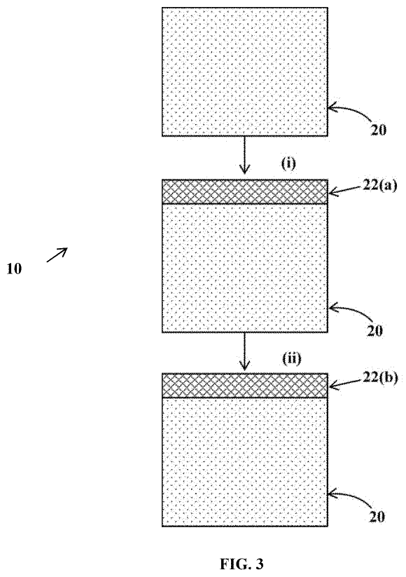

Referring to FIG. 3, illustrated are example steps of a method as described and an example fluorinated yttrium oxide-metal oxide coating as described. According to method 10, substrate 20 is provided and, in step (i), yttrium oxide-metal oxide layer 22(a) is applied to a surface of substrate 20 by atomic layer deposition. In step (ii), substrate 20 with deposited yttrium oxide-metal oxide coating thin film 22(a) is subjected to a fluoro-annealing step that converts at least a portion of the yttrium oxide of yttrium oxide-metal oxide coating 22(a) to fluorinated yttrium oxide, to produce fluorinated yttrium oxide-metal oxide coating 24(b).

A fluorinated yttrium oxide-metal oxide coating as described, that includes at least a portion that contains a high concentration of fluorinated yttrium oxide such as yttrium fluoride (YF₃), can be effective as a protective coating. The protective coating is chemically resistant to various process materials, especially (but not only) to halides that may be present in various types of process chambers during operation to perform manufacturing processes that are known or developed in the future, with certain example processes being described herein.

Fluorinated yttrium oxide compounds, especially yttrium fluoride, can contain a relatively high concentration of fluorine, to provide chemical inertness against fluorine atoms. Additionally, the presence of a non-yttrium oxide metal oxide will increase chemical resistance to non-fluorine halides such as chlorine. Accordingly, the level of chemical resistance achieved by the presently-described fluorinated yttrium oxide-metal oxide coatings can be highly useful or relatively improved as compared to levels of chemical resistance achieved by previous protective materials.

Useful and preferred fluorinated yttrium oxide-metal oxide coatings can also be temperature resistant over extended periods of time, including during use at high temperatures (e.g., in a range from 350 to 500 degrees Celsius) in a semiconductor processing tool. More generally, a useful or preferred fluorinated yttrium oxide-metal oxide coating can be resistant to degradation for extended periods of time at temperatures of up to or in excess of 200, 300, 400, 450, or 500 degrees Celsius.

Equipment, devices, or articles that include a fluorinated yttrium oxide-metal oxide coating as a protective coating can include a substrate that includes the fluorinated yttrium oxide-metal oxide coating formed on a surface of the substrate. Advantageously, because the fluorinated yttrium oxide-metal oxide coating can be prepared by use of two specific processing steps that each involve gas-phase deposition, i.e., atomic layer deposition of an yttrium oxide-containing precursor coating, and fluoro-annealing of the deposited yttrium oxide-containing precursor, the fluorinated yttrium oxide-metal oxide coating that is produced can be effectively and uniformly applied to substrate surfaces that are highly three-dimensional or that have a high aspect ratio. Useful fluorinated yttrium oxide-metal oxide coatings can be applied to three-dimensional surfaces that include channels, grooves, or openings such as structures having a relatively high aspect ratio, e.g., an aspect ratio of up to or greater than 10:1, 20:1, 50:1, 100:1, or greater.

Examples of substrates to which a protective fluorinated yttrium oxide-metal oxide coating as described can be applied include items such as various components of a process chamber (“process chamber components”) used for preparing semiconductor materials, microelectronic devices, and the like. Being resistant to process materials such as halides, including combinations of different halides such as fluorine and chlorine, an fluorinated yttrium oxide-metal oxide coating can be used to protect components of the process chamber in the presence of these and other process materials during operation.

Preferred protective coatings can be prepared to include a low amount of defects such as cracks, fissures, pinholes, and other physical defects. Defects such as pinholes, cracks, and fissures can be identified by visual inspection, optionally with the use of magnification using an optical microscope or a scanning electron microscope, or by other suitable examination methods. Preferred coatings can also be applied to exhibit a high level of coating thickness uniformity across a surface of the coating, especially when compared to coatings applied by other methods, such as by physical vapor deposition. For example, a high level of uniformity can refer to a coating that is less than 2 microns in thickness over an area of 1, 5, or 10 square centimeters, and that does not vary in thickness over that area by more than 20, 10, or 5 percent.

A protective coating as described can be formed on and useful with any surface or substrate upon which a fluorinated yttrium oxide-metal oxide coating may be effectively applied. In particular embodiments, a substrate may be made of a vacuum compatible substrate material and may be in the form of a component of a process chamber that is used to process substrates, materials, or devices by use of one or more different process materials that are highly reactive, corrosive, or otherwise capable of aggressively degrading or reacting with other materials, including internal components of a process chamber. In this context, a fluorinated yttrium oxide-metal oxide coating as described can be advantageously applied to a substrate that is referred to herein as a “vacuum compatible substrate,” and that is formed to function as a component of a process chamber (herein, a “process chamber component” or a “process tool component”) used to process microelectronic devices, semiconductor equipment and devices, precursors thereof, etc., by treatment with a process material that includes a halide or a combination of halides.

A process chamber is useful to contain highly corrosive or reactive process materials that may be in the form of a liquid, gas, or plasma, used, for example, for processing a microelectronic device substrate or semiconductor device substrate during a step of manufacturing a microelectronic or semiconductor device. Particular examples of reactive process materials include bromine plasma, chlorine plasma, and fluorine plasma, e.g., a plasma derived from NF₃, CF₄, C₂F₆, C₃F₈, C₄F₈, F₂, Cl₂, HCl, HF, CHF₃, CH₂F₂, SF₆, BCl₃, CCl₄, or HBr.

The process chamber must contain process chamber components and surfaces that are useful to transport, hold, secure, support, or move a workpiece into, out of, and within the process chamber, without being unduly degraded by process materials that will be present in the process chamber. The process chamber must also contain a system of structures that is effective to flow, deliver, and remove the reactive process materials (e.g., plasma) to and from the interior of the process chamber.

Examples of process chamber components include articles of any shape, including flat, planar, essentially two-dimensional surfaces, but also those that have a more complex shape. Advantageously, the present methods and thin films can be used with substrates that have a physical shape or form that is three-dimensional form, such as a form that includes an opening, aperture, channel, tunnel, a threaded screw, a threaded nut, a porous membrane, a filter, a three-dimensional network, a hole, a channel, an extended surface, or the like, including such features that are considered to have a high aspect ratio. More specific example structures include: flow heads (shower heads), shields, trays, supports, nozzles, valves, conduits, stages for handling or holding a substrate, wafer handling fixtures, chamber liners, ceramic wafer carriers, wafer holders, susceptors, spindles, chucks, rings, baffles, and various types of fasteners (screws, nuts, bolts, clamps, rivets, etc.).

Atomic layer deposition techniques and fluoro-annealing techniques as described are gas-phase deposition techniques that are effective to provide a uniform and high quality deposited thin film on such three dimensional surfaces, including surfaces that have an aspect ratio of at least 10:1, 20:1, 50:1, 100:1, or greater.

A substrate of a process chamber component onto which a fluorinated yttrium oxide-metal oxide coating can be formed can be made from a variety of different solid materials, including materials sometimes referred to as “vacuum-compatible” substrate materials. Generally, examples can include ceramic materials, metals, and a metal alloys that can be coated with a protective coating and used in a process chamber. Examples of ceramic materials that can be useful as a vacuum-compatible substrate include alumina, silicon carbide, silicon, silicon oxide, and aluminum nitride. Examples of metals and metal alloys include nickel, nickel alloys, stainless steel, and aluminum. Vacuum-compatible substrates can also be quartz, sapphire, silica, fused silica, fused quartz, silicon, anodized aluminum, zirconium oxide, glass, as well as plastics such as certain plastics used in the semiconductor industry, e.g., as polyether ether ketone (PEEK) and polyimides.

While the present description refers often to process chambers and process chamber components (e.g., etch chamber components) as useful substrates for a protective coating as described, the described fluorinated yttrium oxide-metal oxide coatings are not limited to use with these items. Various other ceramic, mineral, metal, and metal alloy articles and substrates that would benefit from a protective coating having a high level of resistance to highly reactive chemical materials can also be processed to place an fluorinated yttrium oxide-metal oxide coating at a surface thereof, as described herein.

Aspect 1. A coated substrate comprising: a substrate, and a coating on a surface of the substrate, the coating comprising: fluorinated yttrium oxide, and zirconium oxide.

Aspect 2. The coated substrate of aspect 1, wherein the fluorinated yttrium oxide is selected from yttrium oxyfluoride (YOF), yttrium fluoride (YF₃), and a combination thereof

Aspect 3. The coated substrate of aspect 2, wherein the coating comprises multiple layers including at least one yttrium fluoride layer and at least one zirconium oxide layer.

Aspect 4. The coated substrate of aspect 3, wherein the coating comprises from 3 to 10 total yttrium fluoride and zirconium oxide layers.

Aspect 5. The coated substrate of aspect 4, wherein each layer has a thickness in a range from 2 to 50 nanometers.

Aspect 6. The coated substrate of aspect 3, wherein the coating comprises from 5 to 1000 total yttrium fluoride and zirconium oxide layers.

Aspect 7. The coated substrate of aspect 6, wherein each layer has a thickness in a range from 0.1 to 10 nanometers.

Aspect 8. The coated substrate of aspect 1, wherein the coating is a composite that comprises yttrium fluoride and zirconium oxide.

Aspect 9. The coated substrate of any of aspects 1 through 7, wherein the coating contains less than 20 atomic percent yttrium oxide based on a total amount of yttrium fluoride, yttrium oxide, and yttrium oxyfluoride.

Aspect 10. The coated substrate of any of aspects 1 through 9, wherein the coating is an atomic layer deposition coating.

Aspect 11. The coated substrate of aspect 10, wherein the coating is a fluoro-annealed coating.

Aspect 12. The coated substrate of any of aspects 1 through 11, wherein the substrate includes three-dimensional structure having an aspect ratio of at least 10:1.

Aspect 13. The coated substrate of any of aspects 1 through 12, wherein the substrate is a process tool component of a microelectronic device or semiconductor manufacturing system.

Aspect 14. The coated substrate of any of aspects 1 through 13, wherein the substrate comprises: a wall surface of a plasma etch chamber, a wafer susceptor, a chuck, a showerhead, a liner, a ring, a nozzle, a baffle, a fastener, a wafer support, a wafer transport structure, or a portion or component of any one or these.

Aspect 15. The coated substrate of any of aspects 1 through 13, wherein the substrate includes a three-dimensional feature selected from: a threaded screw, a threaded nut, a porous membrane, a filter, a three-dimensional network, a hole, and a channel.

Aspect 16. The coated substrate of any of aspects 1 through 15, wherein the substrate comprises aluminum, stainless steel, nickel, quartz, glass, or ceramic.

Aspect 17. A method of preparing a coating that contains fluorinated yttrium oxide and zirconium oxide, the method comprising: depositing a coating onto a surface by atomic layer deposition, the coating comprising yttrium oxide and zirconium oxide, and exposing the coating to molecular fluorine source vapor and elevated temperature to convert yttrium oxide of the coating to fluorinated yttrium oxide.

Aspect 18. The method of aspect 17, wherein the fluorinated yttrium oxide is selected from yttrium oxyfluoride (YOF), yttrium fluoride (YF₃), and a combination thereof

Aspect 19. The method of aspect 18, wherein the coating comprises multiple layers including at least one yttrium fluoride layer and at least one zirconium oxide layer.

Aspect 20. The method of aspect 19, wherein the coating comprises from 3 to 10 total yttrium fluoride and zirconium oxide layers.

Aspect 21. The method of aspect 20, wherein each layer has a thickness in a range from 2 to 50 nanometers.

Aspect 22. The method of aspect 19, wherein the coating comprises from 5 to 1000 total yttrium fluoride and zirconium oxide layers.

Aspect 23. The method of aspect 22, wherein each layer has a thickness in a range from 0.1 to 10 nanometers.

Aspect 24. The method of aspect 18, wherein the coating is a composite that comprises yttrium fluoride and zirconium oxide.

Aspect 25. The method of any of aspects 17 through 24, wherein exposing the yttrium oxide to fluorine and elevated temperature converts at least 80 percent of the yttrium oxide of the coating to yttrium fluoride.

Aspect 26. The method of any of aspects 17 through 25, further comprising exposing the yttrium oxide to molecular fluorine source vapor at a temperature of at least 300 degrees Celsius to convert yttrium oxide to yttrium fluoride.

Aspect 27. The method of aspect 26, wherein the molecular fluorine source vapor is derived by heating fluorinated polymer.

Aspect 28. The method of aspect 27, wherein the fluorinated polymer is a homopolymer or copolymer comprising polymerized fluoroolefin monomers.

Aspect 29. The method of aspect 27, wherein the fluorinated polymer comprises: polymerized perfluoroalkylethylene having a C₁-C₁₀ perfluoroalkyl group; polytetrafluoroethylene (PTFE); a tetrafluoroethylene/perfluoro(alkyl vinyl ether) copolymer (PFA); a tetrafluoroethylene/hexafluoropropylene copolymer (FEP); a tetrafluoroethylene/perfluoro(alkyl vinyl ether)/hexafluoropropylene copolymer (EPA); polyhexafluoropropylene; an ethylene/tetrafluoroethylene copolymer (ETFE); poly trifluoroethylene; polyvinylidene fluoride (PVDF); polyvinyl fluoride (PVF); poly chlorotrifluoroethylene (PCTFE); an ethylene/chlorotrifluoroethylene copolymer (ECTFE); or a combination thereof

Aspect 30. The method of aspect 27, wherein the molecular fluorine source vapor comprises CF₄, C₂F₄, C₃F₆, C₄F₈, CHF₃, C₂H₂F₂, C₂F₆, HF, CH₃F, or a combination thereof

Aspect 31. A coated substrate comprising: a substrate, and a coating on a surface of the substrate, the coating comprising: fluorinated yttrium oxide, and a metal oxide that is different from yttrium oxide.

Aspect 32. The coated substrate of aspect 31, wherein the fluorinated yttrium oxide is selected from yttrium oxyfluoride (YOF), yttrium fluoride (YF₃), and a combination thereof

Aspect 33. The coated substrate of aspect 32, wherein the coating comprises multiple layers including at least one yttrium fluoride layer and at least one metal oxide layer.

Aspect 34. The coated substrate of aspect 32, wherein the coating is a composite that comprises yttrium fluoride and a metal oxide that is different from yttrium oxide.

Aspect 35. The coated substrate of any of aspects 30 through 34, wherein the coating is an atomic layer deposition coating.

Aspect 36. The coated substrate of aspect 35, wherein the coating is a fluoro-annealed coating.

Aspect 37. The coated substrate of any of aspects 30 through 36, wherein the substrate is a process tool component of a microelectronic device or semiconductor manufacturing system.

Aspect 38. A method of preparing a coating that contains fluorinated yttrium and a metal oxide that is different from yttrium oxide, the method comprising: depositing a coating onto a surface by atomic layer deposition, the coating comprising yttrium oxide and metal oxide that is different from yttrium oxide, and exposing the coating to molecular fluorine source vapor and elevated temperature to convert yttrium oxide of the coating to fluorinated yttrium oxide.

Aspect 39. The method of aspect 38, wherein the coating comprises multiple layers including at least one yttrium fluoride layer and at least one metal oxide layer.

Aspect 40. The method of aspect 39, wherein the coating comprises from 3 to 10 total yttrium fluoride and metal oxide layers.

Aspect 41. The method of aspect 40, wherein each layer has a thickness in a range from 2 to 50 nanometers.

Aspect 42. The method of aspect 41, wherein the coating comprises from 5 to 1000 total yttrium fluoride and metal oxide layers.

Aspect 43. The method of aspect 42, wherein each layer has a thickness in a range from 0.1 to 10 nanometers.

Aspect 44. The method of aspect 38, wherein the coating is a composite that comprises yttrium fluoride and metal oxide.

What is claimed:

1. A coated substrate comprising:
a substrate, and
a coating on a surface of the substrate, the coating comprising:
fluorinated yttrium oxide, and
zirconium oxide.

2. The coated substrate of claim 1, wherein the fluorinated yttrium oxide is selected from yttrium oxyfluoride (YOF), yttrium fluoride (YF₃), and a combination thereof.

3. The coated substrate of claim 2, wherein the coating comprises multiple layers including at least one yttrium fluoride layer and at least one zirconium oxide layer.

4. The coated substrate of claim 3, wherein the coating comprises from 3 to 10 total yttrium fluoride and zirconium oxide layers.

5. The coated substrate of claim 4, wherein each layer has a thickness in a range from 2 to 50 nanometers.

6. The coated substrate of claim 3, wherein the coating comprises from 5 to 1000 total yttrium fluoride and zirconium oxide layers.

7. The coated substrate of claim 6, wherein each layer has a thickness in a range from 0.1 to 10 nanometers.

8. The coated substrate of claim 1, wherein the substrate comprises: a wall surface of a plasma etch chamber, a wafer susceptor, a chuck, a showerhead, a liner, a ring, a nozzle, a baffle, a fastener, a wafer support, a wafer transport structure, a threaded screw, a threaded nut, a porous membrane, a filter, a three-dimensional network, a hole, and a channel or a portion or component of any one or these.

9. The coated substrate of claim 1, wherein the substrate comprises aluminum, stainless steel, nickel, quartz, glass, or ceramic.

10. A method of preparing a coating that contains fluorinated yttrium oxide and zirconium oxide, the method comprising:
depositing a coating onto a surface by atomic layer deposition, the coating comprising yttrium oxide and zirconium oxide, and
exposing the coating to molecular fluorine source vapor and elevated temperature to convert yttrium oxide of the coating to fluorinated yttrium oxide.

11. The method of claim 10, wherein the fluorinated yttrium oxide is selected from yttrium oxyfluoride (YOF), yttrium fluoride (YF₃), and a combination thereof.

12. The method of claim 10, wherein the coating comprises multiple layers including at least one yttrium fluoride layer and at least one zirconium oxide layer.

13. The method of claim 10, wherein each layer has a thickness in a range from 2 to 50 nanometers.

14. The method of claim 10, wherein each layer has a thickness in a range from 0.1 to 10 nanometers.

15. The method of claim 10, wherein exposing the yttrium oxide to fluorine and elevated temperature converts at least 80 percent of the yttrium oxide of the coating to yttrium fluoride.

16. The method of claim 15, further comprising exposing the yttrium oxide to molecular fluorine source vapor at a temperature of at least 300 degrees Celsius to convert yttrium oxide to yttrium fluoride.

17. The method of claim 16, wherein the molecular fluorine source vapor is derived by heating fluorinated polymer.

18. The method of claim 16, wherein the fluorinated polymer comprises: polymerized perfluoroalkylethylene having a C₁-C₁₀ perfluoroalkyl group; polytetrafluoroethylene (PTFE); a tetrafluoroethylene/perfluoro(alkyl vinyl ether) copolymer (PFA); a tetrafluoroethylene/hexafluoropropylene copolymer (FEP); a tetrafluoroethylene/perfluoro(alkyl vinyl ether)/hexafluoropropylene copolymer (EPA); polyhexafluoropropylene; an ethylene/tetrafluoroethylene copolymer (ETFE); poly trifluoroethylene; polyvinylidene fluoride (PVDF); polyvinyl fluoride (PVF); polychlorotrifluoroethylene (PCTFE); an ethylene/chlorotrifluoroethylene copolymer (ECTFE); or a combination thereof.

19. The method of claim 16, wherein the molecular fluorine source vapor comprises CF₄, C₂F₄, C₃F₆, C₄F₈, CHF₃, C₂H₂F₂, C₂F₆, HF, CH₃F, or a combination thereof.
